(19) United States
(12) Patent Application Publication
(10) Pub. No.: US 2012/0015502 A1
(43) Pub. Date: Jan. 19, 2012

(54) p-GaN Fabrication Process Utilizing a Dedicated Chamber and Method of Minimizing Magnesium Redistribution for Sharper Decay Profile

(76) Inventors: Jie Cui, Albany, CA (US); David Bour, Cupertino, CA (US); Wei-Yung Hsu, Santa Clara, CA (US)

(21) Appl. No.: 13/174,530

(22) Filed: Jun. 30, 2011

Related U.S. Application Data
(60) Provisional application No. 61/364,320, filed on Jul. 14, 2010.

(51) Int. Cl. H01L 21/20; C23C 16/00

(52) U.S. Cl. 438/478; 118/715; 257/E21.09

(57) ABSTRACT

Methods and systems for the fabrication of p-GaN, and related, films utilizing a dedicated chamber in a multi-chamber tool are described. Also described are methods of fabricating a magnesium doped group III-V material layer, such as a GaN layer, with a sharp magnesium decay profile.

### CROSS-REFERENCE TO RELATED APPLICATIONS

This application claims the benefit of U.S. Provisional Application No. 61/364,320, filed Jul. 14, 2010, the entire contents of which are hereby incorporated by reference herein.

### BACKGROUND

1) Field

Embodiments of the present invention pertain to the field of light-emitting diode fabrication and, in particular, to p-GaN fabrication processes utilizing dedicated chambers.

2) Description of Related Art

Group III-V materials are playing an ever increasing role in the semiconductor and related, e.g. light-emitting diode (LED), industries. Often, group III-V materials are difficult to grow or deposit without the formation of defects or cracks. For example, high quality surface preservation of select films, e.g. a gallium nitride film, is not straightforward in many applications using stacks of material layers fabricated sequentially.

### SUMMARY

Disclosed herein are dedicated-chamber-based growth techniques for forming p-type gallium nitride. In one embodiment, a method of fabricating an LED includes using a dedicated chamber to grow the p-GaN portion of the LED.

Also disclosed herein are dedicated-chamber-based growth systems for forming p-type gallium nitride. In one embodiment, a system includes a dedicated chamber for fabricating a p-GaN portion of an LED.

In another embodiment, a method of fabricating a group III-V material layer is provided. The method includes forming a magnesium-doped gallium nitride (GaN) layer above a substrate. The magnesium-doped GaN layer is then modified to form a top Mg₃N₂ layer. The top Mg₃N₂ layer is then removed.

### BRIEF DESCRIPTION OF THE DRAWINGS

FIG. 1 illustrates a cross-sectional view of a GaN-based LED, in accordance with an embodiment of the present invention.

FIG. 2 is a band diagram of a blue InGaN MQW LED under forward bias, in accordance with an embodiment of the present invention.

FIG. 3 is a band diagram of a blue InGaN MQW LED under forward bias, illustrating non-radiative recombination associated with an interfacial defect resulting from chemical contamination, in accordance with an embodiment of the present invention.

FIG. 4A is a schematic cross-sectional view of an MOCVD chamber, in accordance with an embodiment of the present invention.

FIG. 4B is a detailed cross sectional view of the showerhead assembly shown in FIG. 4A, in accordance with an embodiment of the present invention.

FIG. 5 includes a table indicating melting points and solubility factors for various halides of magnesium, in accordance with an embodiment of the present invention.

FIG. 6 illustrates a block diagram of an exemplary computer system, in accordance with an embodiment of the present invention.

FIG. 7 is a schematic view of an HVPE apparatus, in accordance with an embodiment of the present invention.

### DETAILED DESCRIPTION

Dedicated-chamber-based growth techniques and systems for forming p-type gallium nitride, and other such related, films are described. In the following description, numerous specific details are set forth, such as fabrication conditions and material regimes, in order to provide a thorough understanding of embodiments of the present invention. It will be apparent to one skilled in the art that embodiments of the present invention may be practiced without these specific details. In other instances, well-known features, such as facility layouts or specific diode configurations, are not described in detail in order to not unnecessarily obscure embodiments of the present invention. Furthermore, it is to be understood that the various embodiments shown in the Figures are illustrative representations and are not necessarily drawn to scale. Additionally, other arrangements and configurations may not be explicitly disclosed in embodiments herein, but are still considered to be within the spirit and scope of the invention.

Light-emitting diodes (LEDs) and related devices may be fabricated from layers of, e.g., group III-V films. Some embodiments of the present invention relate to forming p-type gallium nitride (p-GaN) layers in a dedicated chamber of a cluster tool, such as in a dedicated metal-organic chemical vapor deposition (MOCVD) chamber or a dedicated hydride vapor phase epitaxy (HVPE) chamber of a cluster tool. In a cluster tool environment, there may be potential for surface cross-contamination between chambers within the cluster tool. In accordance with an embodiment of the present invention, a recovery step is performed to yield a fresh surface during the fabrication of a stack of Group III-V material layers. Key features of certain embodiments of the present invention include: (a) pGaN material layer fabrication, (b) LED fabrication, or (c) p-n interface engineering. In some embodiments of the present invention, p-GaN is a p-type binary GaN film, but in other embodiments, p-GaN is a p-type ternary film (e.g., InGaN, AlGaN) or is a p-type quaternary film (e.g., InAlGaN).

In accordance with an embodiment of the present invention, fabrication of a GaN-based LED via epitaxy processing is performed in three major categories. The first category of processing includes fabrication of an n-type GaN template (e.g., n-type GaN, n-type InGaN, n-type AlGaN, n-type InAlGaN) on a substrate (e.g., planar sapphire substrate, patterned sapphire substrate (PSS), silicon substrate, silicon carbide substrate). The second category of processing includes fabrication of a multiple quantum well (MQW), or active region, structure or film stack on or above the n-type GaN template (e.g., an MQW composed of one or a plurality of field pairs of InGaN well/GaN barrier material layers). The third category of processing includes fabrication of a p-type GaN (p-GaN) structure or film stack on or above the MQW. The p-GaN structure may be a single layer (such as, but not limited to, a single layer of p-type GaN, p-type InGaN, p-type AlGaN, or p-type InAlGaN), or may be a stack of multiple films. In a specific embodiment, the p-GaN structure is a film stack composed of p-type AlGaN and GaN layers.

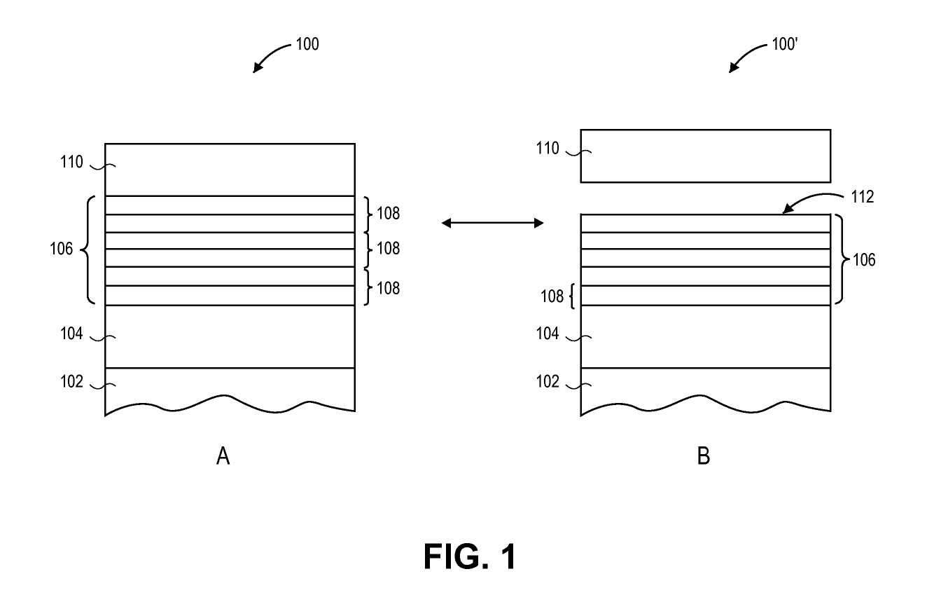

FIG. 1 illustrates a cross-sectional view of a GaN-based LED, in accordance with an embodiment of the present invention. Referring to the structure of part A of FIG. 1, a GaN-based LED 100 includes an n-type GaN template 104 (e.g., n-type GaN, n-type InGaN, n-type AlGaN, n-type InAlGaN) on a substrate 102 (e.g., planar sapphire substrate, patterned sapphire substrate (PSS), silicon substrate, silicon carbide substrate). The GaN-based LED 100 also includes a multiple quantum well (MQW), or active region, structure or film stack 106 on or above the n-type GaN template 104 (e.g., an MQW composed of one or a plurality of field pairs of InGaN well/GaN barrier material layers 108, as depicted in FIG. 1). The GaN-based LED 100 also includes a p-type GaN (p-GaN) structure or film stack 110 on or above the MQW 106. Referring to the structure of part B of FIG. 1, a GaN-based LED 100′ includes all of the features 102, 104, 106, 108 and 110 of structure 100, but is shown to reveal an interface 112 between MQW 106 and p-GaN feature 110 which conceptually exists during the time between the fabrication processes used to form MQW 106 and p-GaN feature 110, as described in further detail below.

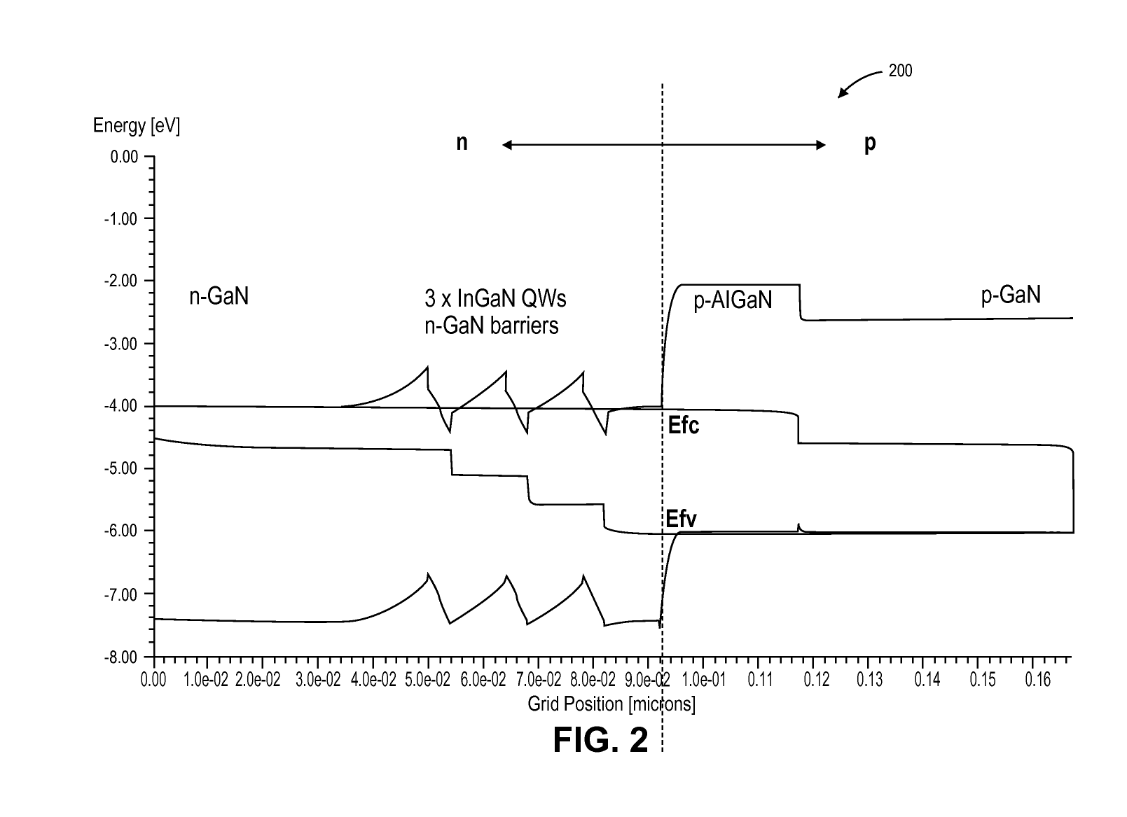

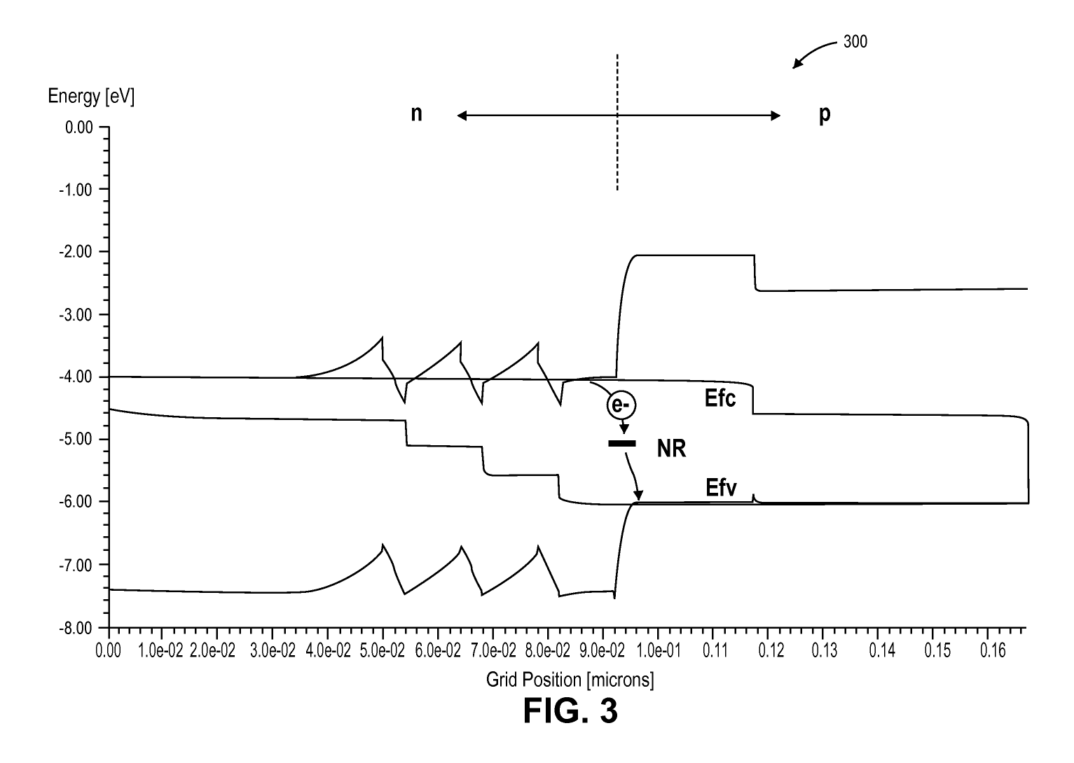

Typically, in a cluster tool environment, although the transfer from chamber-to-chamber is performed under, e.g., a purified nitrogen (N₂) ambient environment, no environment is completely free of contaminants. Therefore, there may be an opportunity for the interface, e.g., interface 112 between MQW 106 and p-GaN feature 110, to become chemically contaminated during the transfer and/or growth interruption. Depending upon the reactivity of the exposed surface, and the nature of the contaminating chemical species, this contamination may have a deleterious impact on LED operation, as illustrated in FIGS. 2 and 3 and described below.

In an embodiment, in a cluster-tool fabrication environment, the fabrication process is split at a p-n junction, e.g., at the interface 112 between MQW 106 and p-GaN feature 110. Specifically, in one embodiment, after the growth of an MQW and a final GaN barrier layer in the MQW, the growth is terminated, the wafer cooled and then transferred robotically to a next chamber via an N₂-purged transfer chamber. In a particular embodiment, in the next chamber, the wafer is heated under an NH₃/N₂/H₂ ambient, and growth initiated with p-type (e.g., magnesium-doped) AlGaN. It is during this growth interruption and transfer that chemical contamination of an interface may occur. In an embodiment, the p-GaN portion is formed with trimethyl gallium (and/or trimethyl aluminum and/or trimethyl indium) and ammonia (NH₃) along with N₂ and/or H₂ carrier gas.

FIG. 2 is a band diagram of a blue InGaN MQW LED under forward bias, in accordance with an embodiment of the present invention. Referring to FIG. 2, a band diagram 200 of an ideal InGaN LED under forward bias is provided. In an embodiment, there is no chemical contamination to produce a defect with an energy that lies within the bandgap, as depicted in FIG. 2.

FIG. 3 is a band diagram of a blue InGaN MQW LED under forward bias, illustrating non-radiative recombination associated with an interfacial defect resulting from chemical contamination, in accordance with an embodiment of the present invention. Referring to FIG. 3, a band diagram 300 showing the non-ideal case with a chemically-contaminated pGaN growth interface is provided. In an embodiment, in this case, some chemical contamination produces a defect with an energy that lies within the bandgap. This defect level can be responsible for non-radiative recombination (NR), as indicated in FIG. 3. In one embodiment, the NR is manifest in at least two symptoms: (1) excessive forward leakage current, and (2) diminished LED light-output efficiency, especially at low currents (N.B. at high current the defect may be saturated).

In accordance with an embodiment of the present invention, a dedicated chamber is provided in a cluster tool for the fabrication of a p-GaN portion of an LED. In an embodiment, the pGaN portion is fabricated, in a dedicated chamber, on an MQW structure, which in turn is fabricated on an n-type or an undoped GaN structure. In one embodiment, by fabricating the p-GaN portion of an LED in a dedicated chamber, light output from a finally fabricated LED is improved by approximately 50%, as demonstrated via electroluminescence testing. In one embodiment, by fabricating the p-GaN portion of an LED in a dedicated chamber, the initialization temperature of a p-AlGaN portion of a p-GaN structure, e.g., to provide a pn junction, can be raised compared with a single chamber process, which would otherwise require formation of the P-GaN portion at approximately the same temperature as the MQW portion. For example, in a specific embodiment, an MQW is fabricated at a temperature of approximately 730 degrees Celsius, while a p-GaN portion is formed in a separate, dedicated, chamber at an initialization temperature (e.g., the temperature upon introduction of a wafer to the chamber) of approximately 780 degrees Celsius, or even as high as 800 degrees Celsius. In one embodiment, by fabricating the p-GaN portion of an LED in a dedicated chamber, a precursor pre-conditioning, e.g., with a magnesium (Mg) metal-organic p-type dopant precursor, can be performed to reduce a dopant (e.g., Mg) memory effect and turn-on delay. In a particular embodiment, a memory effect and turn-on delay is reduced for the p-type dopant, CP₂Mg.

In accordance with an embodiment of the present invention, improvements associated with an improved process using a dedicated chamber for a p-GaN portion of an LED may be interpreted in one or more several ways. For example, in one embodiment, the capability of heating to a higher temperature prior to p-GaN growth may be effective in desorbing chemical contaminants so that they are not incorporated. This may be expected, for example, if the contaminant is oxygen. In one embodiment, heating to a higher temperature may accomplish some chemical etching of the surface, e.g., to remove 1-2 nm of the contaminated layer from the surface and therefore provide a fresh surface, especially if H₂ is present. In one embodiment, preconditioning with a Cp2Mg precursor allows more accurate formation of the p-n junction, for improved injection efficiency and may, likewise, allow for higher p-type doping in the vicinity of the junction to improve electron confinement. For example, in a specific embodiment, normally, Cp₂Mg molecules become stuck in a delivery channel, and thus delay a response to turn-on time. However, in a dedicated chamber, flow of the precursor may be performed prior to use.

In accordance with an embodiment of the present invention, the upper limit of the p-GaN growth temperature is determined by the MQW stability. In this case, the temperature for p-GaN growth may be increased by approximately 20 degrees Celsius. In one embodiment, higher temperatures are viable and beneficial, so long as the MQW quality is preserved. In a specific embodiment, compared to a baseline process not including a dedicated chamber for p-GaN formation, the quick-electroluminescence increased from ˜40 to ˜60 using the above improved process.

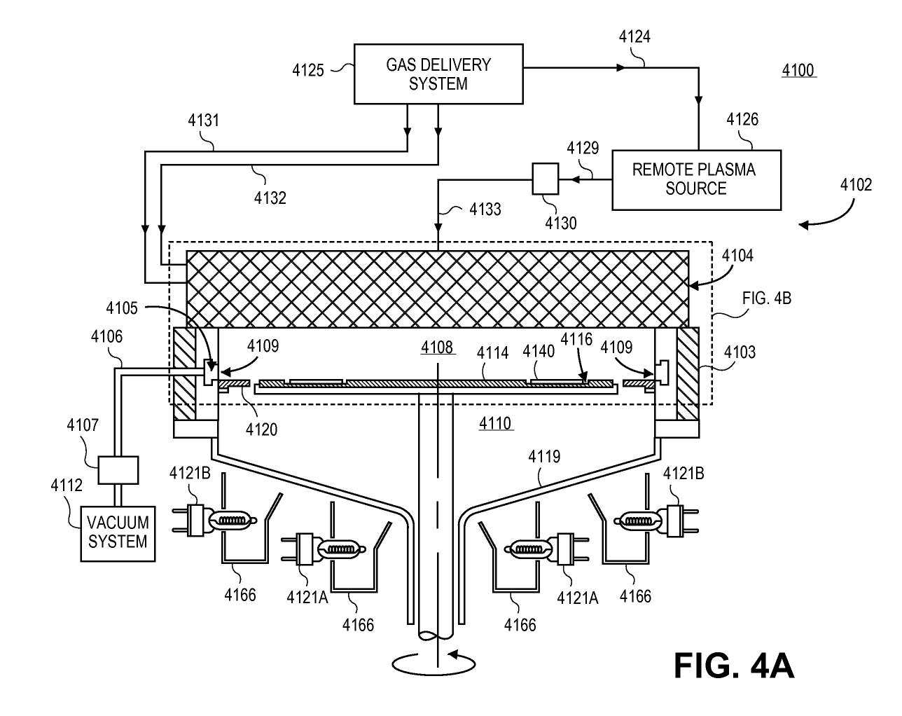

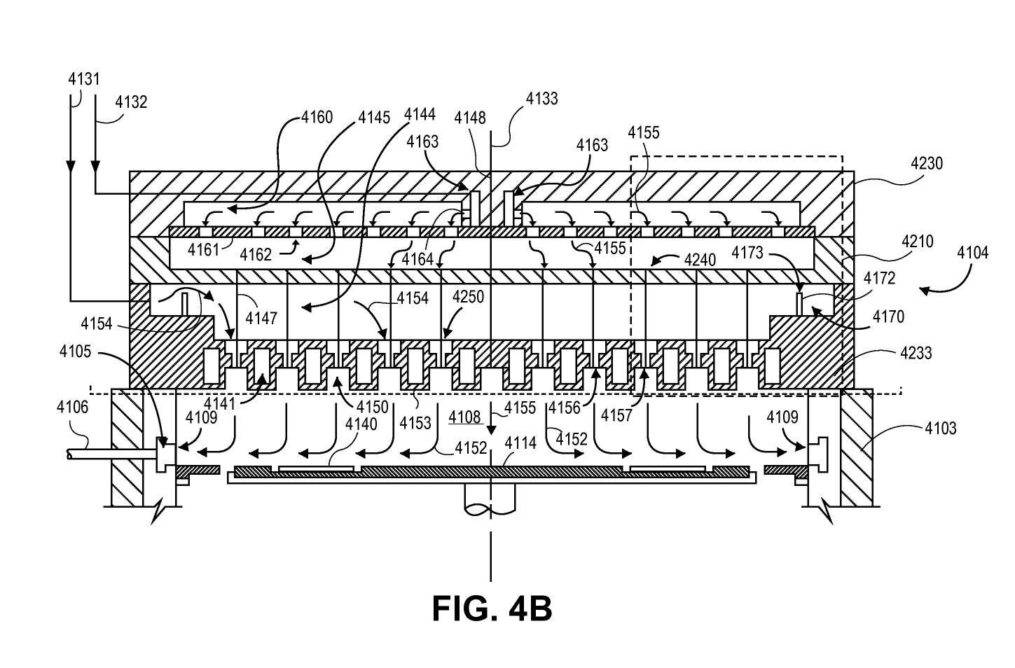

An example of an MOCVD deposition chamber which may be utilized for dedicated growth of pGaN or a related film, in accordance with embodiments of the present invention, is illustrated and described with respect to FIGS. 4A and 4B.

FIG. 4A is a schematic cross-sectional view of an MOCVD chamber according to an embodiment of the invention. Exemplary systems and chambers that may be adapted to practice the present invention are described in U.S. patent application Ser. No. 11/404,516, filed on Apr. 14, 2006, and Ser. No. 11/429,022, filed on May 5, 2006, both of which are incorporated by reference in their entireties.

The apparatus 4100 shown in FIG. 1A comprises a chamber 4102, a gas delivery system 4125, a remote plasma source 4126, and a vacuum system 4112. The chamber 4102 includes a chamber body 4103 that encloses a processing volume 4108. A showerhead assembly 4104 is disposed at one end of the processing volume 4108, and a substrate carrier 4114 is disposed at the other end of the processing volume 4108. A lower dome 4119 is disposed at one end of a lower volume 4110, and the substrate carrier 4114 is disposed at the other end of the lower volume 4110. The substrate carrier 4114 is shown in process position, but may be moved to a lower position where, for example, the substrates 4140 may be loaded or unloaded. An exhaust ring 4120 may be disposed around the periphery of the substrate carrier 4114 to help prevent deposition from occurring in the lower volume 4110 and also help direct exhaust gases from the chamber 4102 to exhaust ports 4109. The lower dome 4119 may be made of transparent material, such as high-purity quartz, to allow light to pass through for radiant heating of the substrates 4140. The radiant heating may be provided by a plurality of inner lamps 4121A and outer lamps 4121B disposed below the lower dome 4119, and reflectors 4166 may be used to help control chamber 4102 exposure to the radiant energy provided by inner and outer lamps 4121A, 4121B. Additional rings of lamps may also be used for finer temperature control of the substrates 4140.

The substrate carrier 4114 may include one or more recesses 4116 within which one or more substrates 4140 may be disposed during processing. The substrate carrier 4114 may carry six or more substrates 4140. In one embodiment, the substrate carrier 4114 carries eight substrates 4140. It is to be understood that more or less substrates 4140 may be carried on the substrate carrier 4114. Typical substrates 4140 may include sapphire, silicon carbide (SiC), silicon, or gallium nitride (GaN). It is to be understood that other types of substrates 4140, such as glass substrates 4140, may be processed. Substrate 4140 size may range from 50 mm-100 mm in diameter or larger. The substrate carrier 4114 size may range from 200 mm-750 mm. The substrate carrier 4114 may be formed from a variety of materials, including SiC or SiC-coated graphite. It is to be understood that substrates 4140 of other sizes may be processed within the chamber 4102 and according to the processes described herein. The showerhead assembly 4104, as described herein, may allow for more uniform deposition across a greater number of substrates 4140 and/or larger substrates 4140 than in traditional MOCVD chambers, thereby increasing throughput and reducing processing cost per substrate 4140.

The substrate carrier 4114 may rotate about an axis during processing. In one embodiment, the substrate carrier 4114 may be rotated at about 2 RPM to about 100 RPM. In another embodiment, the substrate carrier 4114 may be rotated at about 30 RPM. Rotating the substrate carrier 4114 aids in providing uniform heating of the substrates 4140 and uniform exposure of the processing gases to each substrate 4140.

The plurality of inner and outer lamps 4121A, 4121B may be arranged in concentric circles or zones (not shown), and each lamp zone may be separately powered. In one embodiment, one or more temperature sensors, such as pyrometers (not shown), may be disposed within the showerhead assembly 4104 to measure substrate 4140 and substrate carrier 4114 temperatures, and the temperature data may be sent to a controller (not shown) which can adjust power to separate lamp zones to maintain a predetermined temperature profile across the substrate carrier 4114. In another embodiment, the power to separate lamp zones may be adjusted to compensate for precursor flow or precursor concentration non-uniformity. For example, if the precursor concentration is lower in a substrate carrier 4114 region near an outer lamp zone, the power to the outer lamp zone may be adjusted to help compensate for the precursor depletion in this region.

The inner and outer lamps 4121A, 4121B may heat the substrates 4140 to a temperature of about 400 degrees Celsius to about 1200 degrees Celsius. It is to be understood that the invention is not restricted to the use of arrays of inner and outer lamps 4121A, 4121B. Any suitable heating source may be utilized to ensure that the proper temperature is adequately applied to the chamber 4102 and substrates 4140 therein. For example, in another embodiment, the heating source may comprise resistive heating elements (not shown) which are in thermal contact with the substrate carrier 4114.

A gas delivery system 4125 may include multiple gas sources, or, depending on the process being run, some of the sources may be liquid sources rather than gases, in which case the gas delivery system may include a liquid injection system or other means (e.g., a bubbler) to vaporize the liquid. The vapor may then be mixed with a carrier gas prior to delivery to the chamber 4102. Different gases, such as precursor gases, carrier gases, purge gases, cleaning/etching gases or others may be supplied from the gas delivery system 4125 to separate supply lines 4131, 4132, and 4133 to the showerhead assembly 4104. The supply lines 4131, 4132, and 4133 may include shut-off valves and mass flow controllers or other types of controllers to monitor and regulate or shut off the flow of gas in each line.

A conduit 4129 may receive cleaning/etching gases from a remote plasma source 4126. The remote plasma source 4126 may receive gases from the gas delivery system 4125 via supply line 4124, and a valve 4130 may be disposed between the showerhead assembly 4104 and remote plasma source 4126. The valve 4130 may be opened to allow a cleaning and/or etching gas or plasma to flow into the showerhead assembly 4104 via supply line 4133 which may be adapted to function as a conduit for a plasma. In another embodiment, apparatus 4100 may not include remote plasma source 4126 and cleaning/etching gases may be delivered from gas delivery system 4125 for non-plasma cleaning and/or etching using alternate supply line configurations to shower head assembly 4104.

The remote plasma source 4126 may be a radio frequency or microwave plasma source adapted for chamber 4102 cleaning and/or substrate 4140 etching. Cleaning and/or etching gas may be supplied to the remote plasma source 4126 via supply line 4124 to produce plasma species which may be sent via conduit 4129 and supply line 4133 for dispersion through showerhead assembly 4104 into chamber 4102. Gases for a cleaning application may include fluorine, chlorine or other reactive elements.

In another embodiment, the gas delivery system 4125 and remote plasma source 4126 may be suitably adapted so that precursor gases may be supplied to the remote plasma source 4126 to produce plasma species which may be sent through showerhead assembly 4104 to deposit CVD layers, such as III-V films, for example, on substrates 4140.

A purge gas (e.g., nitrogen) may be delivered into the chamber 4102 from the showerhead assembly 4104 and/or from inlet ports or tubes (not shown) disposed below the substrate carrier 4114 and near the bottom of the chamber body 4103. The purge gas enters the lower volume 4110 of the chamber 4102 and flows upwards past the substrate carrier 4114 and exhaust ring 4120 and into multiple exhaust ports 4109 which are disposed around an annular exhaust channel 4105. An exhaust conduit 4106 connects the annular exhaust channel 4105 to a vacuum system 4112 which includes a vacuum pump (not shown). The chamber 4102 pressure may be controlled using a valve system 4107 which controls the rate at which the exhaust gases are drawn from the annular exhaust channel 4105.

FIG. 4B is a detailed cross sectional view of the showerhead assembly shown in FIG. 4A, in accordance with an embodiment of the present invention. The showerhead assembly 4104 is located near the substrate carrier 4114 during substrate 4140 processing. In one embodiment, the distance from the showerhead face 4153 to the substrate carrier 4114 during processing may range from about 4 mm to about 41 mm. In one embodiment, the showerhead face 4153 may comprise multiple surfaces of the showerhead assembly 4104 which are approximately coplanar and face the substrates 4140 during processing.

During substrate 4140 processing, according to one embodiment of the invention, process gas 4152 flows from the showerhead assembly 4104 towards the substrate 4140 surface. The process gas 4152 may comprise one or more precursor gases as well as carrier gases and dopant gases which may be mixed with the precursor gases. The draw of the annular exhaust channel 4105 may affect gas flow so that the process gas 4152 flows substantially tangential to the substrates 4140 and may be uniformly distributed radially across the substrate 4140 deposition surfaces in a laminar flow. The processing volume 4108 may be maintained at a pressure of about 760 Torr down to about 80 Torr.

Reaction of process gas 4152 precursors at or near the substrate 4140 surface may deposit various metal nitride layers upon the substrate 4140, including GaN, aluminum nitride (AlN), and indium nitride (InN). Multiple metals may also be utilized for the deposition of other compound films such as AlGaN and/or InGaN. Additionally, dopants, such as silicon (Si) or magnesium (Mg), may be added to the films. The films may be doped by adding small amounts of dopant gases during the deposition process. For silicon doping, silane (SiH₄) or disilane (Si₂H₆) gases may be used, for example, and a dopant gas may include Bis(cyclopentadienyl)magnesium (Cp₂Mg or (C₅H₅)₂Mg) for magnesium doping.

In one embodiment, the showerhead assembly 4104 comprises an annular manifold 4170, a first plenum 4144, a second plenum 4145, a third plenum 4160, gas conduits 4147, blocker plate 4161, heat exchanging channel 4141, mixing channel 4150, and a central conduit 4148. The annular manifold 4170 encircles the first plenum 4144 which is separated from the second plenum 4145 by a mid-plate 4210 which has a plurality of mid-plate holes 4240. The second plenum 4145 is separated from the third plenum 4160 by blocker plate 4161 which has a plurality of blocker plate holes 4162 and the blocker plate 4161 is coupled to a top plate 4230. The mid-plate 4210 includes a plurality of gas conduits 4147 which are disposed in mid-plate holes 4240 and extend down through first plenum 4144 and into bottom plate holes 4250 located in a bottom plate 4233. The diameter of each bottom plate hole 4250 decreases to form a first gas injection hole 4156 which is generally concentric or coaxial to gas conduit 4147 which forms a second gas injection hole 4157. In another embodiment, the second gas injection hole 4157 may be offset from the first gas injection hole 4156 wherein the second gas injection hole 4157 is disposed within the boundary of the first gas injection hole 4156. The bottom plate 4233 also includes heat exchanging channels 4141 and mixing channels 4150 which comprise straight channels which are parallel to each other and extend across showerhead assembly 4104.

The showerhead assembly 4104 receives gases via supply lines 4131, 4132, and 4133. In another embodiment, each supply line 4131, 4132 may comprise a plurality of lines which are coupled to and in fluid communication with the showerhead assembly 4104. A first precursor gas 4154 and a second precursor gas 4155 flow through supply lines 4131 and 4132 into annular manifold 4170 and top manifold 4163. A non-reactive gas 4151, which may be an inert gas such as hydrogen (H₂), nitrogen (N₂), helium (He), argon (Ar) or other gases and combinations thereof, may flow through supply line 4133 coupled to a central conduit 4148 which is located at or near the center of the showerhead assembly 4104. The central conduit 4148 may function as a central inert gas diffuser which flows a non-reactive gas 4151 into a central region of the processing volume 4108 to help prevent gas recirculation in the central region. In another embodiment, the central conduit 4148 may carry a precursor gas.

In another aspect of the present invention, methods of minimizing magnesium (Mg) redistribution in group III-V films are provided to target sharper decay profiles of Mg in such films. For example, in one embodiment, a method of minimizing a long Mg-tail otherwise observed during regrowth of a non-Mg doped layer on Mg doped GaN is provided. In a specific such embodiment, an in-situ clean with a halogen-based gas is used. In another specific embodiment, an in-situ water vapor treatment is used. In yet another specific embodiment, an in-situ scavenging is performed with liquid phase indium.

Mg is primarily used as an acceptor for MOCVD-grown GaN. The “memory effect” of Mg may cause a turn on and turn off delay of Mg doping profiles in GaN layers. However, issues may arise from the low vapor pressure of the Mg precursor, Cp₂Mg, and the related adduct formed with NH₃ (e.g., either a 1:1 adduct or a 2:1 adduct). For example, the precursor or such adducts may condense in a gas delivery line or on chamber walls of a reaction chamber. Another challenge may be Mg redistribution, which can be observed in the regrowth of non-p-type GaN on the p-GaN with a slow Mg decay profile even if a Cp₂Mg source. This may occur even in a Mg-free chamber, which indicates that Mg-rich accumulation on the surface is likely responsible for the problem. Ex-situ acid-based etching may be used to remove the excessive Mg-rich layer and to yield a sharp Mg decay profile. In addition, regrowth at lower temperatures, such as around 825° C., may also suppress the Mg redistribution. Furthermore, an AlN interlayer may be used to suppress the Mg redistribution in the GaN regrowth layer.

In an embodiment, Mg doping in a manner to provide a sharp decay profile is critical in some device applications, such as n+/p+ tunnel junction formation, npn GaN FET formation with a regrowth n-type layer on p-GaN layer, or p-down type LED with InGaN MQWs on p-GaN. Therefore, achieving sharp Mg doping profiles or sharp Mg decay profiles in the non-p-type GaN layer may be desirable. For example, in an embodiment, a method of minimization of Mg-redistribution is provided without sacrificing production throughput, modification of the device structure, or deterioration of the crystal and interface quality.

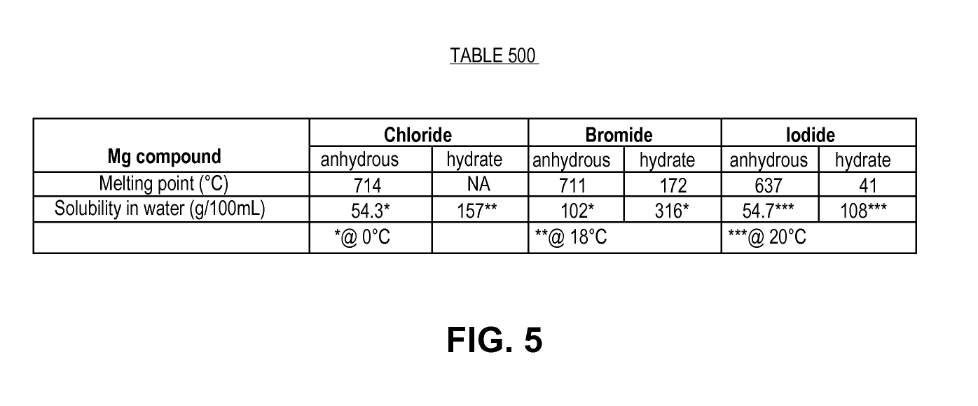

In accordance with one or more embodiments of the present invention, in-situ methods are used to suppress Mg redistribution and to achieve a sharp Mg decay profile. For example, Mg redistribution in a gallium nitride film may provide a Mg rich layer composed of Mg₃N₂, which is has high stability and a melting point around 1500° C. In one embodiment, in-situ etching is used to remove a magnesium rich layer with halogen based gas by converting Mg₃N₂ into one or more species with lower melting points. FIG. 5 includes a table 500 indicating melting points and solubility factors for various halides of magnesium, in accordance with an embodiment of the present invention. In an embodiment, magnesium of the Mg₃N₂ is converted to MgCl₂, MgBr₂, or MgI₂, melting points and solubility points for which are provided in table 500. In one such embodiment, the MgCl₂, MgBr₂, or MgI₂ is removed by dissolution in water. In another such embodiment, the MgCl₂, MgBr₂, or MgI₂ is removed by volatilization.

In another embodiment, Mg₃N₂ is reacted with water to form magnesium hydroxide (e.g., with a low meting point at approximately 350° C.). An exemplary reaction is Mg₃N₂+6H₂O→3Mg(OH)₂+2NH₃, Mg(OH)₂. Either of the above approaches may be used to convert Mg₃N₂ into one or more volatile or soluble compounds to facilitate the removal of excessive Mg on the p-GaN surface. In another embodiment, liquid-phase indium is used to scavenge the excessive Mg on the surface by forming In—Mg eutectic alloys. The Mg-containing indium layer may be removed during a temperature ramping up, e.g., prior to regrowth of the magnesium-doped GaN layer. The above embodiments may result in a “Mg-free” surface.

It is to be understood that embodiments of the present invention are not limited to formation of layers on patterned sapphire substrates. Other embodiments may include the use of any suitable patterned single crystalline substrate upon which a Group III-Nitride epitaxial film may be formed. The patterned substrate may be formed from a substrate, such as but not limited to a sapphire (Al₂O₃) substrate, a silicon carbide (SiC) substrate, a silicon on diamond (SOD) substrate, a quartz (SiO₂) substrate, a glass substrate, a zinc oxide (ZnO) substrate, a magnesium oxide (MgO) substrate, and a lithium aluminum oxide (LiAlO₂) substrate. Any well know method, such as masking and etching may be utilized to form features, such as the posts described above, from a planar substrate to create a patterned substrate. In a specific embodiment, however, the patterned substrate is a (0001) patterned sapphire substrate (PSS). Patterned sapphire substrates may be ideal for use in the manufacturing of LEDs because they increase the light extraction efficiency which is extremely useful in the fabrication of a new generation of solid state lighting devices. Other embodiments include the use of planar (non-patterned) substrates, such as a planar sapphire substrate.

In some embodiments, growth on the substrate is performed along a (0001) Ga-polarity, N-polarity, or non-polar a-plane {112-0} or m-plane {101-0}, or semi-polar planes. In some embodiments, posts formed in a patterned growth substrate are round, triangular, hexagonal, rhombus shape, or other shapes effective for block-style growth. In an embodiment, the patterned substrate contains a plurality of features (e.g., posts) having a cone shape. In a particular embodiment, the feature has a conical portion and a base portion. In an embodiment of the present invention, the feature has a tip portion with a sharp point to prevent over growth. In an embodiment, the tip has an angle (Θ) of less than 145° and ideally less than 110°. Additionally, in an embodiment, the feature has a base portion which forms a substantially 90° angle with respect to the xy plane of the substrate. In an embodiment of the present invention, the feature has a height greater than one micron and ideally greater than 1.5 microns. In an embodiment, the feature has a diameter of approximately 3.0 microns. In an embodiment, the feature has a diameter height ratio of approximately less than 3 and ideally less than 2. In an embodiment, the features (e.g., posts) within a discrete block of features (e.g., within a block of posts) are spaced apart by a spacing of less than 1 micron and typically between 0.7 to 0.8 microns.

It is also to be understood that embodiments of the present invention need not be limited to pGaN as a group layer formed on a patterned substrate. For example, other embodiments may include any Group III-Nitride epitaxial film that can be suitably deposited by hydride vapor phase epitaxy or MOCVD, or the like, deposition. The Group III-Nitride film may be a binary, ternary, or quaternary compound semiconductor film formed from a group III element or elements selected from gallium, indium and aluminum and nitrogen. That is, the Group III-Nitride crystalline film can be any solid solution or alloy of one or more Group III element and nitrogen, such as but not limited to GaN, AlN, InN, AlGaN, InGaN, InAlN, and InGaAlN. However, in a specific embodiment, the Group III-Nitride film is a p-type gallium nitride (GaN) film. The Group III-Nitride film can have a thickness between 2-500 microns and is typically formed between 2-15 microns. Thicknesses greater than 500 microns are possible because of, e.g., the high growth rate of HVPE. In an embodiment of the present invention, the Group III-Nitride film has a thickness of at least 3.0 microns to sufficiently suppress threading dislocations. Additionally, as described above, the Group III-Nitride film can be doped. The Group III-Nitride film can be p-typed doped using any p-type dopant such as but not limited Mg, Be, Ca, Sr, or any Group I or Group II element have two valence electrons. The Group III-Nitride film can be p-type doped to a conductivity level of between 1×10¹⁶ to 1×10²⁰ atoms/cm³.

It is to be understood that although the above description is focused on dedicated chambers with a cluster tool, other tools with more than one chamber, e.g. an in-line tool, may also be arranged to have a dedicated chamber for fabricating a p-GaN portion of an LED. Also, the p-GaN portion need not be the only portion with a dedicated chamber. For example, dedicated chambers may be contemplated for the MQW portion and/or the n-type (or undoped) GaN portions of an LED.

Embodiments of the present invention may be provided as a computer program product, or software, that may include a machine-readable medium having stored thereon instructions, which may be used to program a computer system (or other electronic devices) to perform a process according to the present invention. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

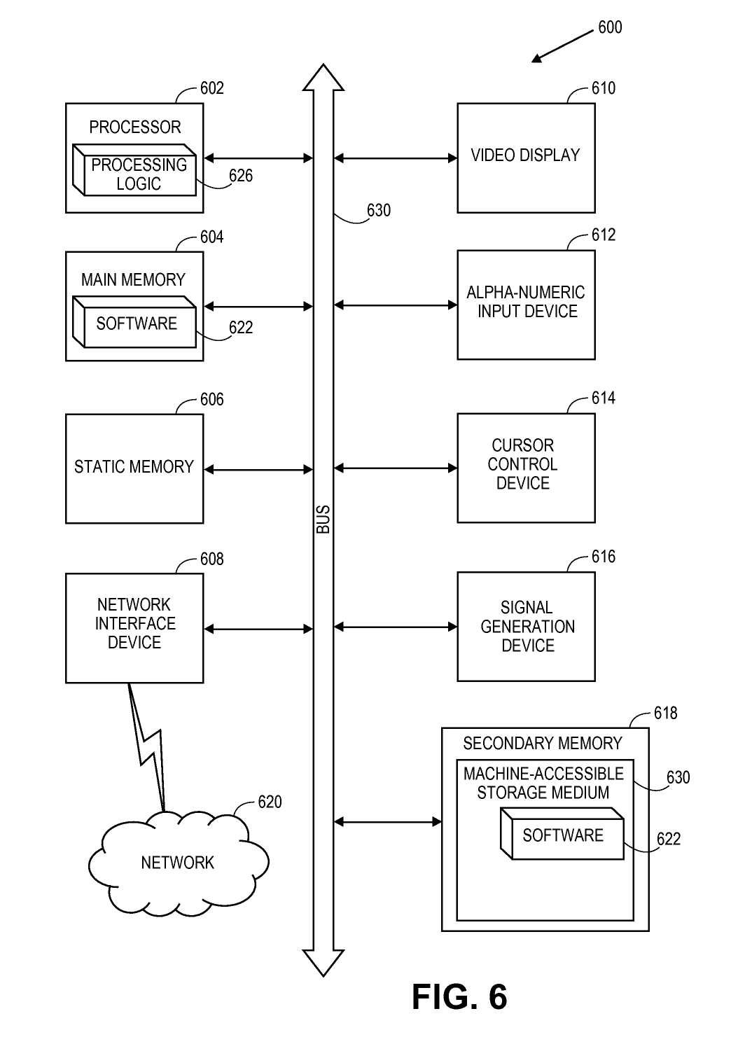

FIG. 6 illustrates a diagrammatic representation of a machine in the exemplary form of a computer system 600 within which a set of instructions, for causing the machine to perform any one or more of the processes discussed herein, may be executed. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the processes discussed herein.

The exemplary computer system 600 includes a processor 602, a main memory 604 (e.g., read-only memory (ROM), flash memory, dynamic random access memory (DRAM) such as synchronous DRAM (SDRAM) etc., a static memory 606 (e.g., flash memory, static random access memory (SRAM), etc.), and a secondary memory 618 (e.g., a data storage device), which communicate with each other via a bus 630.

Processor 602 represents one or more general-purpose processing devices such as a microprocessor, central processing unit, or the like. More particularly, the processor 602 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 602 may also be one or more special-purpose processing devices such as an application specific integrated circuit (ASIC), a field programmable gate array (FPGA), a digital signal processor (DSP), network processor, or the like. Processor 602 is configured to execute the processing logic 626 for performing the processes discussed herein.

The computer system 600 may further include a network interface device 608. The computer system 600 also may include a video display unit 610 (e.g., a liquid crystal display (LCD) or a cathode ray tube (CRT)), an alphanumeric input device 612 (e.g., a keyboard), a cursor control device 614 (e.g., a mouse), and a signal generation device 1216 (e.g., a speaker).

The secondary memory 618 may include a machine-accessible storage medium (or more specifically a computer-readable storage medium) 631 on which is stored one or more sets of instructions (e.g., software 622) embodying any one or more of the methodologies or functions described herein. The software 622 may also reside, completely or at least partially, within the main memory 604 and/or within the processor 602 during execution thereof by the computer system 600, the main memory 604 and the processor 602 also constituting machine-readable storage media. The software 622 may further be transmitted or received over a network 620 via the network interface device 608.

While the machine-accessible storage medium 631 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies of the present invention. The term “machine-readable storage medium” shall accordingly be taken to include, but not be limited to, solid-state memories, and optical and magnetic media.

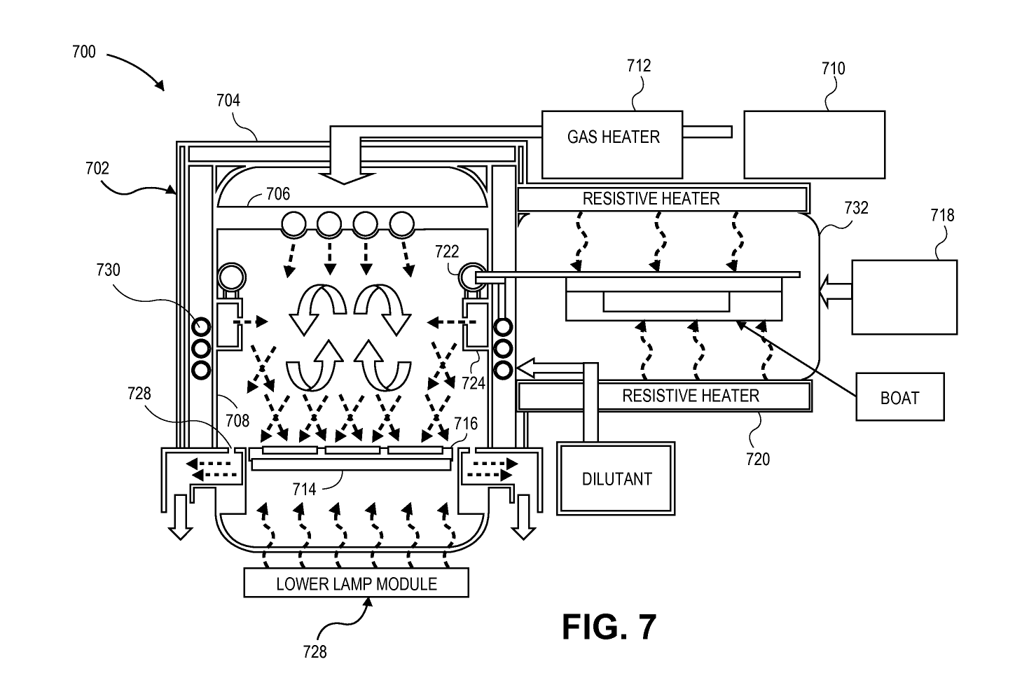

An example of a HVPE deposition chamber which may be utilized for dedicated growth of pGaN or a related film or for forming a p-GaN film with a sharp decay profile, in accordance with embodiments of the present invention, is illustrated and described with respect to FIG. 7.

FIG. 7 is a schematic view of an HVPE apparatus 700 according to one embodiment. The apparatus includes a chamber 702 enclosed by a lid 704. Processing gas from a first gas source 710 is delivered to the chamber 702 through a gas distribution showerhead 706. In one embodiment, the gas source 710 may comprise a nitrogen containing compound. In another embodiment, the gas source 710 may comprise ammonia. In one embodiment, an inert gas such as helium or diatomic nitrogen may be introduced as well either through the gas distribution showerhead 706 or through the walls 708 of the chamber 702. An energy source 712 may be disposed between the gas source 710 and the gas distribution showerhead 706. In one embodiment, the energy source 712 may comprise a heater. The energy source 712 may break up the gas from the gas source 710, such as ammonia, so that the nitrogen from the nitrogen containing gas is more reactive.

To react with the gas from the first source 710, precursor material may be delivered from one or more second sources 718. The precursor may be delivered to the chamber 702 by flowing a reactive gas over and/or through the precursor in the precursor source 718. In one embodiment, the reactive gas may comprise a chlorine containing gas such as diatomic chlorine. The chlorine containing gas may react with the precursor source to form a chloride. In order to increase the effectiveness of the chlorine containing gas to react with the precursor, the chlorine containing gas may snake through the boat area in the chamber 732 and be heated with the resistive heater 720. By increasing the residence time that the chlorine containing gas is snaked through the chamber 732, the temperature of the chlorine containing gas may be controlled. By increasing the temperature of the chlorine containing gas, the chlorine may react with the precursor faster. In other words, the temperature is a catalyst to the reaction between the chlorine and the precursor.

In order to increase the reactiveness of the precursor, the precursor may be heated by a resistive heater 720 within the second chamber 732 in a boat. The chloride reaction product may then be delivered to the chamber 702. The reactive chloride product first enters a tube 722 where it evenly distributes within the tube 722. The tube 722 is connected to another tube 724. The chloride reaction product enters the second tube 724 after it has been evenly distributed within the first tube 722. The chloride reaction product then enters into the chamber 702 where it mixes with the nitrogen containing gas to form a nitride layer on the substrate 716 that is disposed on a susceptor 714. In one embodiment, the susceptor 714 may comprise silicon carbide. The nitride layer may comprise p-type gallium nitride for example. The other reaction products, such as nitrogen and chlorine, are exhausted through an exhaust 726.

Thus, techniques for fabrication of p-GaN, and related, films utilizing a dedicated chamber approach have been disclosed. In accordance with an embodiment of the present invention, a method of fabricating an LED includes using a dedicated chamber to grow the p-GaN portion of the LED. In accordance with an embodiment of the present invention, a system includes a dedicated chamber for fabricating a p-GaN portion of an LED.

What is claimed is:

1. A method of fabricating a group III-V based device, the method comprising:
providing a substrate to a dedicated p-type gallium nitride (p-GaN) chamber in a multi-chamber tool; and
forming, above the substrate, a p-GaN portion of the group III-V based device in the dedicated chamber.

2. The method of claim 1, further comprising:
prior to forming the p-GaN portion of the group III-V based device, forming an MQW portion of the group III-V based device at a first temperature in a growth chamber of the multi-chamber tool, wherein the p-GaN portion is then formed at a second, higher temperature in the dedicated chamber, the dedicated chamber different from the growth chamber.

3. The method of claim 2, wherein the second temperature is approximately 50 degrees Celsius higher than the first temperature.

4. The method of claim 2, wherein the second temperature is approximately in the range of 780-800 degrees Celsius, and wherein the first temperature is approximately 730 degrees Celsius.

5. The method of claim 1, further comprising:
prior to forming the p-GaN portion of the group III-V based device, preconditioning the dedicated chamber with a p-type precursor.

6. The method of claim 5, wherein the p-type precursor is Cp₂Mg.

7. The method of claim 1, wherein the p-GaN portion of the group III-V based device comprises magnesium-doped GaN.

8. The method of claim 1, wherein the p-GaN portion of the group III-V based device comprises magnesium-doped AlGaN.

9. The method of claim 1, wherein the p-GaN portion of the group III-V based device comprises magnesium-doped InGaN.

10. The method of claim 1, wherein the p-GaN portion of the group III-V based device comprises magnesium-doped InAlGaN.

11. A system having a dedicated chamber for fabricating a p-GaN portion of a group III-V based device.

12. A method of fabricating a group III-V material layer, the method comprising:
forming a magnesium-doped gallium nitride (GaN) layer above a substrate;
modifying the magnesium-doped GaN layer to form a top Mg₃N₂ layer; and
removing the top Mg₃N₂ layer.

13. The method of claim 12, wherein removing the top Mg₃N₂ layer comprises converting the top Mg₃N₂ layer into a species having a melting point lower than the melting point of Mg₃N₂.

14. The method of claim 13, wherein removing the top Mg₃N₂ layer further comprises volatilizing the species having the melting point lower than the melting point of Mg₃N₂.

15. The method of claim 12, wherein removing the top Mg₃N₂ layer comprises reacting the top Mg₃N₂ layer with water to form magnesium hydroxide.

16. The method of claim 15, wherein removing the top Mg₃N₂ layer further comprises volatilizing the magnesium hydroxide.

17. The method of claim 12, wherein removing the top Mg₃N₂ layer comprises reacting the top Mg₃N₂ layer with liquid-phase indium.

18. The method of claim 17, wherein the liquid-phase indium scavenges Mg from the Mg₃N₂ to form In—Mg eutectic alloys.

19. The method of claim 12, wherein modifying the magnesium-doped GaN layer to form a top Mg₃N₂ layer comprises heating the magnesium-doped GaN layer.

20. The method of claim 12, wherein modifying the magnesium-doped GaN layer to form a top Mg₃N₂ layer comprises forming another group III-V material layer on the magnesium-doped GaN layer.
